(19) United States
(12) Patent Application Publication
(10) Pub. No.: US 2023/0197564 A1
(43) Pub. Date: Jun. 22, 2023

(54) HEAT DISSIPATION STRUCTURE AND ELECTRONIC APPARATUS

(71) Applicant: Lenovo (Singapore) Pte. Ltd., Singapore (SG)

(72) Inventors: Junki Hashiba, Kanagawa (JP); Masahiro Kitamura, Kanagawa (JP); Akinori Uchino, Kanagawa (JP); Yusuke Onoue, Kanagawa (JP)

(73) Assignee: Lenovo (Singapore) Pte. Ltd., Singapore (SG)

(21) Appl. No.: 17/937,781

(22) Filed: Oct. 4, 2022

(30) Foreign Application Priority Data
Dec. 16, 2021 (JP) 2021-204268

(51) Int. Cl. H01L 23/427; H01L 25/16; H01L 23/00

(52) U.S. Cl. CPC H01L 23/427; H01L 25/16; H01L 24/29; H01L 24/32; H01L 2224/29105; H01L 2224/32245

(57) ABSTRACT

A heat dissipation structure, for a semiconductor chip in which a die is provided on a surface of a substrate and an electric element is provided around the die, includes: a heat transfer plate thermally connected to a surface of the die; a liquid metal provided between the surface of the die and the heat transfer plate; and an insulating material covering the electric element. The heat transfer plate has a recessed portion in a location facing the electric element.

### CROSS-REFERENCE TO RELATED APPLICATIONS

This application claims priority to Japanese Patent Application No. 2021-204268 filed on Dec. 26, 2021, the contents of which are hereby incorporated herein by reference in their entirety.

### TECHNICAL FIELD

The present invention relates to a heat dissipation structure for a semiconductor chip in which a die is provided on the surface of a substrate and an electric element is provided around the die, and an electronic apparatus.

### BACKGROUND

Electronic apparatuses include semiconductor chips such as CPUs and GPUs. A CPU or a GPU is shaped to have a substrate which is a part to be mounted on a board and a rectangular die provided on the surface of the substrate. Small capacitors may be provided around the die on the surface of the substrate.

A semiconductor chip such as a CPU or a GPU is a heating element, and requires heat dissipation depending on its power consumption (especially when highly loaded). As a means of dissipating heat from the CPU or GPU, a heat dissipator such as a vapor chamber, a heat spreader, or a heat sink may be used, and brought into contact with the surface of the die to diffuse heat. A heat transfer plate may be interposed between the heat dissipator and the die. Grease or liquid metal having high thermal conductivity may be provided between the die and the heat dissipator or the heat transfer plate, in order to efficiently transfer heat (for example, Japanese Unexamined Patent Application Publication No. 2004-146819). Liquid metal has higher thermal conductivity than grease, and can effectively transfer heat from the die to the heat dissipator.

Liquid metal is electrically conductive, and may contain gallium as a main component and chemically react with solder. Since the liquid metal is liquid and has high fluidity, measures need to be taken to prevent the liquid metal from leaking out to the surrounding board and the like. Even in the case where the liquid metal flows out to the surroundings of the die, the liquid metal needs to be kept from coming into contact with electric elements such as capacitors around the die, because the liquid metal is electrically conductive and is likely to short-circuit the capacitors. In view of this, the electric elements provided on the substrate may be protected using an insulating adhesive.

A CPU die is lower than a GPU die in some cases. For such a CPU die, the gap between the substrate and the heat transfer plate is narrow. Since the adhesive has a certain height, a sufficient gap between the adhesive and the heat transfer plate cannot be secured or interference can occur.

One conceivable way of securing an appropriate gap between the adhesive and the heat transfer plate is to interpose a copper block or the like between the heat transfer plate and the CPU to thus raise the height. However, if the heat transfer plate and the copper block are soldered, there is a possibility that the solder chemically reacts with the liquid metal. Nickel-plating the copper block including the soldered part can prevent the chemical reaction, but causes a cost increase. Moreover, raising the height increases the thickness of the product, which is against the demand for thickness reduction in application to laptop PCs and the like.

### SUMMARY

One or more embodiments of the present invention provides a heat dissipation structure and an electronic apparatus that enable effective heat dissipation of a semiconductor chip and can be produced at low costs.

A heat dissipation structure according to one or more embodiments of the present invention is a heat dissipation structure for a semiconductor chip in which a die is provided on a surface of a substrate and an electric element is provided around the die, the heat dissipation structure including: a heat transfer plate thermally connected to a surface of the die; a liquid metal provided between the surface of the die and the heat transfer plate; and an insulating material covering the electric element, wherein the heat transfer plate has a recessed portion in a location facing the electric element.

An electronic apparatus according to one or more embodiments of the present invention includes the heat dissipation structure and the semiconductor chip.

According to the above-described aspects of the present invention, the liquid metal is provided between the surface of the die and the heat transfer plate, so that the semiconductor chip can dissipate heat effectively. The heat transfer plate having the recessed portion is easy to manufacture, and can be produced at low costs.

The recessed portion may be a through hole, and the through hole may be closed with an insulating sheet. The through hole can be formed easily by punching or the like. The liquid metal is kept from entering the through hole closed with the sheet.

The recessed portion may be a bottomed hole. The bottomed hole can be formed easily by pressing or the like.

The heat dissipation structure may include an elastic material surrounding the die and sandwiched between the substrate and the heat transfer plate, and the elastic material may cover the electric element with the insulating material therebetween. Thus, the electric element is doubly protected by the insulating material and the elastic material.

The insulating material may be adhered to the substrate. Thus, the liquid metal is kept from approaching the electric element along the surface of the substrate, so that the electric element is protected more reliably.

A gap may be formed between the insulating material and the die. Thus, the leaked liquid metal is stored in the gap and prevented from further spreading accidentally.

The semiconductor chip may be a CPU mounted on a board, and the electric element may be a capacitor.

The insulating material may be an ultraviolet curable coating material. The insulating material can be formed easily using such a coating material.

According to the above-described aspects of the present invention, the liquid metal is provided between the surface of the die and the heat transfer plate, so that the semiconductor chip can dissipate heat effectively. The heat transfer plate having the recessed portion is easy to manufacture, and can be produced at low costs.

### BRIEF DESCRIPTION OF THE DRAWINGS

FIG. 1 is an exploded perspective view illustrating a heat dissipation structure and part of an electronic apparatus according to one or more embodiments of the present invention.

FIG. 2 is a perspective view of a CPU.

FIG. 3 is a schematic cross-sectional side view of the heat dissipation structure according to one or more embodiments.

FIG. 4 is a perspective view of a heat transfer plate in one or more embodiments.

FIG. 5 is a schematic plan view illustrating the positional relationship of components in the heat dissipation structure according to one or more embodiments.

FIG. 6 is a schematic cross-sectional side view of a heat dissipation structure according to one or more embodiments of the present invention.

FIG. 7 is a perspective view of a heat transfer plate in one or more embodiments.

FIG. 8 is a schematic cross-sectional side view of a heat dissipation structure according to one or more embodiments of the present invention.

### DETAILED DESCRIPTION

Embodiments of the present invention will be described in detail below, with reference to the drawings. Note that the present invention is not limited to these embodiments.

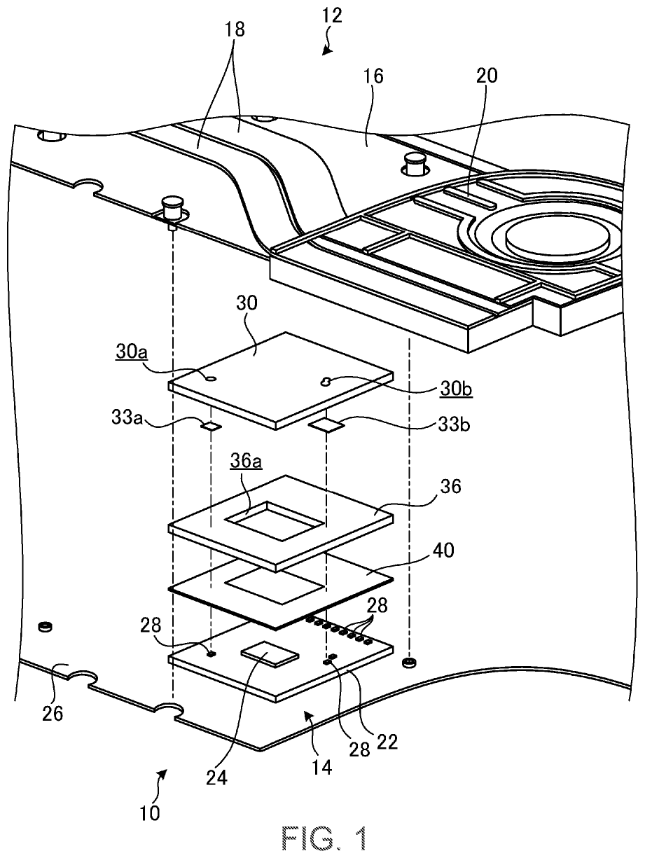

FIG. 1 is an exploded perspective view illustrating a heat dissipation structure 10 and part of an electronic apparatus 12 according to one or more embodiments of the present invention.

The electronic apparatus 12 is, for example, a laptop PC, a desktop PC, a tablet terminal, or a smartphone, and includes a central processing unit (CPU) 14. The CPU 14 performs high-speed computation and thus generates heat accordingly, so that heat dissipation is needed. The electronic apparatus 12 includes a vapor chamber 16 as a heat dissipation means for the CPU 14. The electronic apparatus 12 may include a graphics processing unit (GPU), besides the CPU 14. Although the heat dissipation structures 10, 10A, and 10B described below are used for the CPU 14 as an example, these heat dissipation structures are also usable for other semiconductor chips such as a GPU.

The vapor chamber 16 is a plate-shaped member obtained by joining the edges of two metal plates (e.g. copper plates) to form a closed space inside, and can diffuse heat with high efficiency by the phase change of a working fluid enclosed in the closed space. A wick that delivers the condensed working fluid by capillary action is located in the closed space of the vapor chamber 16.

Two substantially parallel heat pipes 18 are provided in the vapor chamber 16. The heat pipes 18 have their ends connected to a fan 20. Each heat pipe 18 is a thin flat metal pipe having a closed space formed inside, in which a working fluid is enclosed. A wick is located in the heat pipe 18, as in the vapor chamber 16.

The heat dissipation means for the heating element such as the CPU 14 is not limited to the vapor chamber 16, and various heat dissipators are applicable. Examples of heat dissipators include metal plates with high thermal conductivity such as copper and aluminum, graphite plates, heat lanes, and heat sinks.

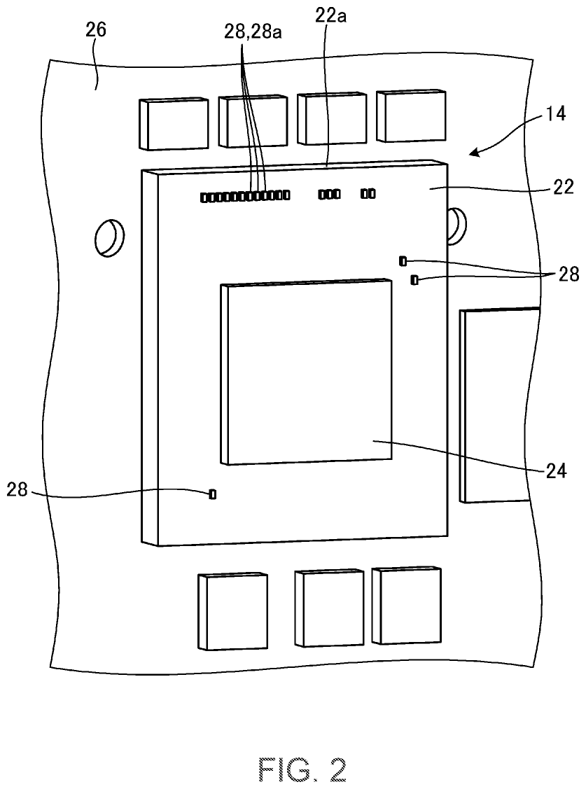

FIG. 2 is a perspective view of the CPU 14. The components of the heat dissipation structure 10 are omitted in FIG. 2. The top and bottom of the heat dissipation structure 10 are not limited in a state in which the heat dissipation structure 10 is incorporated in the electronic apparatus 12 and used, and the heat dissipation structure 10 may be, for example, upside down.

The CPU 14 includes a substrate 22 and a die 24. The substrate 22 is a thin plate-shaped portion mounted on a board 26, and is rectangular in a plan view. The die 24 is a portion including an arithmetic circuit, and slightly protrudes from the surface of the substrate 22. The die 24 has a rectangular shape smaller than that of the substrate 22 in a plan view, and is located approximately at the center of the surface of the substrate 22. The CPU 14 is one of the components that generate the most heat in the electronic apparatus 12, and the die 24 in particular generates heat.

A plurality of small capacitors (electric elements) 28 are provided on the surface of the substrate 22. Several capacitors 28 are located relatively close to the die 24, and many capacitors 28 are arranged along one edge 22a of the substrate 22. The capacitors 28 arranged along the edge 22a are also referred to as capacitors 28a. The height of the capacitors 28 is lower than that of the die 24.

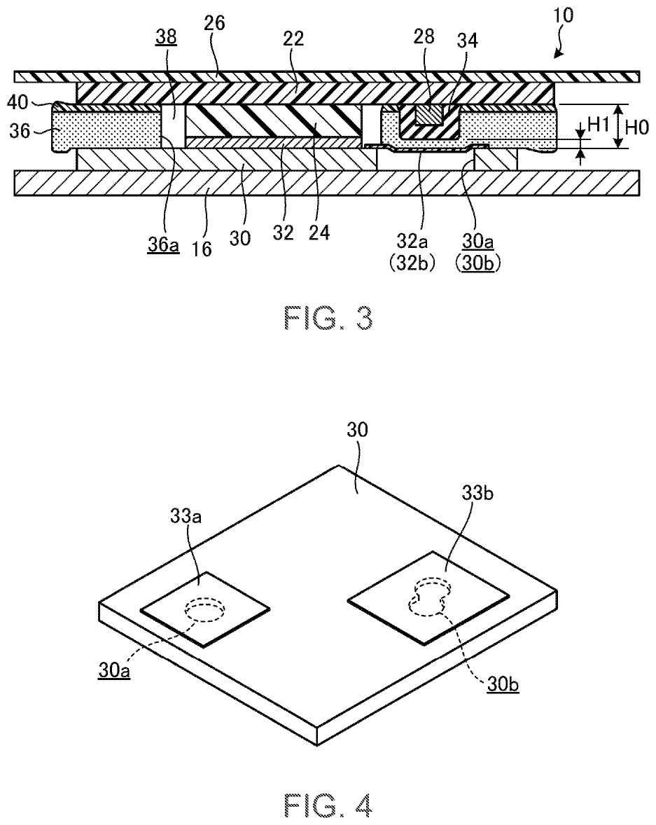

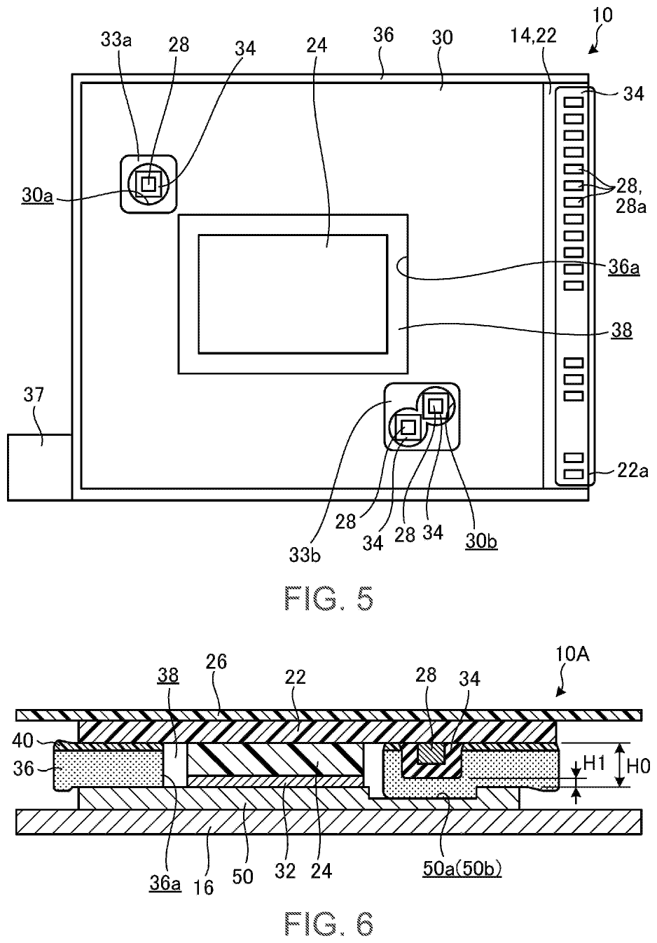

FIG. 3 is a schematic cross-sectional side view of the heat dissipation structure 10 according to one or more embodiments. FIG. 4 is a perspective view of a heat transfer plate 30 according to one or more embodiments. FIG. 5 is a schematic plan view illustrating the positional relationship of components in the heat dissipation structure 10 according to one or more embodiments. In FIG. 5, the vapor chamber 16 and the board 26 are omitted, and each component is illustrated in solid lines regardless of whether it is located in front of or behind another component.

The heat dissipation structure 10 includes the vapor chamber 16, the heat transfer plate 30 thermally connected to the vapor chamber 16, a liquid metal 32 provided between the surface of the die 24 and the heat transfer plate 30, an insulating material 34 covering the capacitors 28, and an elastic material 36 provided between the substrate 22 and the heat transfer plate 30. The heat transfer plate 30 is thermally connected to the surface of the die 24 via the liquid metal 32.

The liquid metal 32 is basically a metal that is liquid at room temperature, but is liquid at temperatures in a normal use state in which the CPU 14 is in operation. The liquid metal 32 is metal, and therefore has excellent thermal conductivity and electrical conductivity. For example, the liquid metal 32 is mainly made of gallium.

The insulating material 34 is, for example, an ultraviolet curable coating material, and is formed in a film shape. The coating material is applied so as to cover the capacitors 28 and then irradiated with ultraviolet rays to cure and form the insulating material 34. The insulating material 34 can be easily formed using such an ultraviolet curable coating material. The insulating material 34 may be any other insulating adhesive or the like.

The elastic material 36 has a rectangular shape slightly larger than that of the substrate 22, and protrudes slightly from the substrate 22. A rectangular hole 36a is formed approximately at the center of the elastic material 36. The elastic material 36 is sandwiched between the substrate 22 and the heat transfer plate 30. In one or more embodiments, however, the part of the elastic material 36 covering the capacitors 28a along the edge 22a of the substrate 22 (see FIG. 5) is not in contact with the heat transfer plate 30. The die 24 is fitted in the rectangular hole 36a. A small gap 38 is secured between the die 24 and the hole wall of the rectangular hole 36a. The elastic material 36 is adhered and fixed to the surface of the substrate 22 by adhesive tape 40 of the same shape in a plan view. The elastic material 36 is slightly higher than the die 24 in a natural state without external force, and is appropriately compressed by the heat transfer plate 30 in an assembled state of the heat dissipation structure 10. For example, the elastic material 36 is made of an insulating material such as a sponge material. The elastic material 36 is a material that does not absorb the liquid metal 32. The elastic material 36 is provided with a pull tab 37 (see FIG. 5) for removal.

The heat transfer plate 30 is made of a material having excellent heat transference, and is, for example, a copper plate. The heat transfer plate 30 has a thickness of about 0.3 mm to 2 mm, for example. The heat transfer plate 30 has substantially the same rectangular shape and area as the substrate 22, but is shaped so as not to face the capacitors 28a along the edge 22a of the substrate 22 (see FIG. 5). Hence, the heat transfer plate 30 and the capacitors 28a do not interfere with each other.

The heat transfer plate 30 is fixed to the vapor chamber 16 by soldering or the like. The heat transfer plate 30 may be subjected to surface treatment such as nickel plating. The heat transfer plate 30 has through holes (recessed portions) 30a and 30b in the locations facing the capacitors 28. The through hole 30a is located facing one capacitor 28, and has a relatively small area corresponding to one capacitor 28. The through hole 30b is located facing two adjacent capacitors 28, and has a relatively large area corresponding to two capacitors 28.

The through holes 30a and 30b are covered with sheets 33a and 33b respectively. The sheets 33a and 33b are insulating, elastic, and flexible. The sheet 33a has an area suitable for covering the through hole 30a. The sheet 33b has an area suitable for covering the through hole 30b, and is slightly larger than the sheet 33a. The sheets 33a and 33b are rectangular or circular, for example. The sheets 33a and 33b are not made of any special material and are inexpensive. Attaching the sheets 33a and 33b so as to cover the through holes 30a and 30b is a simple operation that can be easily performed even by an unskilled worker and can be automated.

An appropriate amount of the liquid metal 32 is applied to the top surface of the die 24 in the assembly stage of the heat dissipation structure 10. The vapor chamber 16 and the heat transfer plate 30 are then placed, as a result of which the liquid metal 32 is pressed by the heat transfer plate 30 and spreads evenly over the surface of the die 24, thus filling the gap between the die 24 and the heat transfer plate 30. Since the liquid metal 32 is liquid, the liquid metal 32 has fluidity and spreads sufficiently when pressed by the heat transfer plate 30. Accordingly, at the microlevel, the heat transfer plate 30 and the die 24 are in direct contact with each other in some parts, and the liquid metal 32 fills the small gaps in the other parts. This allows efficient thermal conduction between the die 24 and the heat transfer plate 30, and can improve the heat dissipation of the CPU 14.

The height H0 of the die 24 is lower in the CPU 14 than in a GPU or the like in some cases. In such a case, the gap between the substrate 22 and the heat transfer plate 30 is narrow. Since the insulating material 34 has a certain height H1, a sufficient gap between the insulating material 34 and the heat transfer plate 30 cannot be secured or interference can occur with the conventional technology.

In the heat dissipation structure 10 and the electronic apparatus 12 according to one or more embodiments, on the other hand, the heat transfer plate 30 has the through holes 30a and 30b as recessed portions in the locations facing the capacitors 28 so as to provide escape spaces. Thus, the insulating material 34 covering the capacitors 28 can be prevented from interfering with the heat transfer plate 30, and also the elastic material 36 can be interposed therebetween. The term “recessed portion” herein denotes a portion that is recessed from the surface regardless of whether it is a through hole or a bottomed hole. The through holes 30a and 30b are covered with the sheets 33a and 33b, but the heat transfer plate 30 itself has recessed portions. Since the sheet bodies have high flexibility and elasticity, the function of the through holes 30a and 30b as escape spaces can be maintained.

The through holes 30a and 30b are covered with the sheets 33a and 33b. Accordingly, even in the case where the liquid metal 32 leaks out from the gap between the die 24 and the heat transfer plate 30, the liquid metal 32 is kept from entering the through holes 30a and 30b, and the solder as the connecting portion between the heat transfer plate 30 and the vapor chamber 16 is protected. The elastic material 36 comes into contact with the sheets 33a and 33b and may press the sheets 33a and 33b lightly, but the sheets 33a and 33b are typically elastic and flexible and deform appropriately. Moreover, the elastic material 36 itself is elastic, too, so that no excessive external force is exerted on the insulating member 34 and the capacitors 28.

The capacitors 28 are doubly insulated by the insulating material 34 and the elastic material 36, and protected from the leaked liquid metal 32. Even in the case where the insulating material 34 and the elastic material 36 near the capacitors 28 peel off and the capacitors 28 come into contact with the sheets 33a and 33b, a short circuit with the heat transfer plate 30 is prevented because the sheets 33a and 33b have insulating property. Since the insulating material 34 is adhered to the substrate 22 with the adhesive tape 40, the liquid metal 32 is kept from approaching the capacitors 28 along the surface of the substrate 22, and therefore the capacitors 28 are protected more reliably. In addition, the gap 38 is secured between the insulating material 34 and the die 24, so that the leaked liquid metal 32 is stored in the gap 38 and is prevented from further spreading accidentally.

The through holes 30a and 30b of the heat transfer plate 30 can be formed easily by punching or the like at low costs. Moreover, the through holes 30a and 30b can be formed at the same time as cutting out the external shape by punching or the like in the manufacturing process of the heat transfer plate 30, with it being possible to further reduce the manufacturing costs. By making only the center part of the heat transfer plate 30 as the contact portion with the die 24 slightly thick and making the other peripheral part of the heat transfer plate 30 thin, a relatively large gap with the insulating material 34 can be secured to thus avoid interference. However, reducing the thickness of the whole peripheral part of the heat transfer plate 30 which is a thin plate requires precision and needs CNC processing and the like, which increases the number of manufacturing steps and increases the costs. Forming the through holes 30a and 30b in the heat transfer plate 30 as in one or more embodiments, on the other hand, is low in cost.

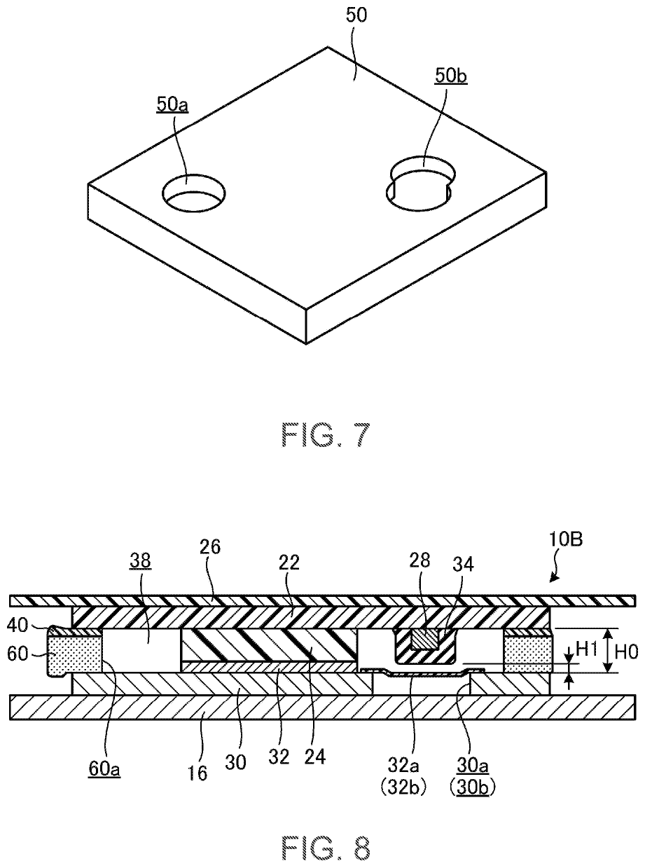

FIG. 6 is a schematic cross-sectional side view of a heat dissipation structure 10A according to one or more embodiments of the present invention. FIG. 7 is a perspective view of a heat transfer plate 50 in one or more embodiments. The heat dissipation structure 10A includes the heat transfer plate 50 instead of the heat transfer plate 30 in the heat dissipation structure 10.

The heat transfer plate 50 has the same size, shape, and material as the heat transfer plate 30, but differs from the heat transfer plate 30 in that the through holes 30a and 30b are replaced with bottomed holes (recessed portions) 50a and 50b with an appropriate depth. The bottomed hole 50a has the same position and the same area as the through hole 30a. The bottomed hole 50b has the same position and the same area as the through hole 30b. The heat transfer plate 50 is not provided with the sheets 33a and 33b.

In the heat dissipation structure 10A, the heat transfer plate 50 has the bottomed holes 50a and 50b as recessed portions in the locations facing the capacitors 28. Thus, the insulating material 34 covering the capacitors 28 can be prevented from interfering with the heat transfer plate 50, and also the elastic material 36 can be interposed therebetween. The elastic material 36 enters the bottomed holes 50a and 50b and may come into contact with their bottom surfaces. However, since the bottomed holes 50a and 50b have an appropriate depth, compression is not significant, and no excessive external force is exerted on the insulating member 34 and the capacitors 28. The bottomed holes 50a and 50b can be formed easily, for example, by pressing the heat transfer plate 50. An insulating coating may be provided on the bottom surface of each of the bottomed holes 50a and 50b.

FIG. 8 is a schematic cross-sectional side view of a heat dissipation structure 10B according to one or more embodiments of the present invention. The heat dissipation structure 10B includes an elastic material 60 instead of the elastic material 36 in the heat dissipation structure 10. The elastic material 60 has the same outer edge shape, thickness, and material as the elastic material 36, but differs from the elastic material 36 in that the rectangular hole 36a is replaced with a rectangular hole 60a having a larger area. The rectangular hole 60a is formed slightly smaller than the outer edges of the heat transfer plate 30. That is, the elastic material 60 is compressed on all four sides by the part along the outer edges of the heat transfer plate 30, and does not exist at the capacitors 28, the through holes 30a and 30b, and the sheets 33a and 33b. Thus, depending on the design conditions, the elastic material 60 is provided along the outer edges of the heat transfer plate 30 and surrounds at least the die 24. This prevents the liquid metal 32 from leaking out to the surrounding board 26 and the like. The heat transfer plate 30 in the heat dissipation structure 10B may be replaced with the heat transfer plate 50 (see FIG. 7).

Depending on the design conditions, the heat transfer plate 30 or 50 may be omitted and the vapor chamber 16 may be thermally connected to the die 24 via the liquid metal 32 in each embodiment. That is, the vapor chamber 16 itself may be used as a heat transfer plate for the die 24.

The present invention is not limited to the embodiments described above, and changes can be made freely without departing from the gist of the present invention.

### DESCRIPTION OF SYMBOLS

10, 10A, 10B heat dissipation structure
12 electronic apparatus
14 CPU (semiconductor chip)
16 vapor chamber
22 substrate
24 die
26 board
28, 28a capacitor (electric element)
30, 50 heat transfer plate
30a, 30b through hole (recessed portion)
32 liquid metal
33a, 33b sheet
34 insulating material
36, 60 elastic material
36a, 60a rectangular hole
38 gap
50a, 50b bottomed hole (recessed portion)

What is claimed is:

1. A heat dissipation structure for a semiconductor chip in which a die is provided on a surface of a substrate and an electric element is provided around the die, the heat dissipation structure comprising:
a heat transfer plate thermally connected to a surface of the die;
a liquid metal provided between the surface of the die and the heat transfer plate; and
an insulating material covering the electric element,
wherein the heat transfer plate has a recessed portion in a location facing the electric element.

2. The heat dissipation structure according to claim 1, wherein the recessed portion is a through hole, and
wherein the through hole is closed with an insulating sheet.

3. The heat dissipation structure according to claim 1, wherein the recessed portion is a bottomed hole.

4. The heat dissipation structure according to claim 1, comprising an elastic material surrounding the die and sandwiched between the substrate and the heat transfer plate,
wherein the elastic material covers the electric element with the insulating material therebetween.

5. The heat dissipation structure according to claim 4, wherein the insulating material is adhered to the substrate.

6. The heat dissipation structure according to claim 4, wherein a gap is formed between the insulating material and the die.

7. The heat dissipation structure according to claim 1, wherein the semiconductor chip is a CPU mounted on a board, and the electric element is a capacitor.

8. The heat dissipation structure according to claim 1, wherein the insulating material is an ultraviolet curable coating material.

9. An electronic apparatus comprising:
a semiconductor chip in which a die is provided on a surface of a substrate and an electric element is provided around the die;
a heat transfer plate thermally connected to a surface of the die;
a liquid metal provided between the surface of the die and the heat transfer plate; and
an insulating material covering the electric element,
wherein the heat transfer plate has a recessed portion in a location facing the electric element.
